(19) United States
(12) Patent Application Publication
(10) Pub. No.: US 2008/0237650 A1
(43) Pub. Date: Oct. 2, 2008

(54) ELECTRODE STRUCTURE FOR FRINGE FIELD CHARGE INJECTION

(75) Inventors: George G. Malliaras, Ithaca, NY (US); Kiyotaka Mori, Cambridge (GB); Hon Hang Fong, Ithaca, NY (US)

Correspondence Address: RATNERPRESTIA, P.O. BOX 980, VALLEY FORGE, PA, 19482, US

(73) Assignees: MATSUSHITA ELECTRIC INDUSTRIAL CO., LTD., Osaka (JP); CORNELL RESEARCH FOUNDATION, INC., Ithaca, NY (US)

(21) Appl. No.: 11/694,136

(22) Filed: Mar. 30, 2007

(51) Int. Cl. H01L 29/76; H01L 21/339

(52) U.S. Cl. 257/214; 438/144; 257/E29.227; 257/E21.456; 977/734

(57) ABSTRACT

A semiconductor device, including: a semiconductor material and an electrode structure electrically coupled to the semiconductor material. The electrode structure includes: a first portion formed of a first conductive material and a second portion formed of a second conductive material. Both the first portion and the second portion of the electrode structure are in direct contact with the semiconductor material. The first conductive material has a first work function and the second conductive material has a second work function that is different from the first work function, so that the second portion of the electrode structure forms a junction with the first portion. The first portion and the second portion of the electrode structure are arranged such that the fringe field from the edge of this junction between the first portion and the second portion extends into the semiconductor material.

### FIELD OF THE INVENTION

The present invention concerns electrode structures designed to provide fringe field charge injection. These electrode structures may allow for the manufacture of improved and/or simplified electronic devices.

### BACKGROUND OF THE INVENTION

Charge injection into the semiconductor materials of electronic devices plays a significant role in device efficiency, as well as device quality.

In particular, the performance of organic semiconductor devices, such as organic light emitting diodes (OLED's) and polymer light emitting diodes (PLED's), has been limited by the relatively high charge injection resistance of organic semiconductor materials. To overcome the charge injection resistance, low work function metals are typically used in organic semiconductor devices. These metals improve charge injection. Low work function metals, such as, for example, calcium, are very susceptible to oxidation and may be easily damaged by air or humidity. Thus, the use of electrodes formed of such materials may necessitate incorporating, potentially complex, encapsulation structures in the design and manufacture of these devices.

Doping of the semiconductor materials may also be used to improve charge injection into the semiconductor materials of electronic devices. In the case of inorganic semiconductor devices, it is common for the semiconductor materials to be heavily doped near the electrodes to form an ohmic contact. However, in some devices the level of doping used to form an ohmic contact may be undesirable, particularly if the dopants may be capable of significant diffusion during operation.

### SUMMARY OF THE INVENTION

The present invention provides an alternative electrode structure that may provide improved charge injection into semiconductor materials of electronic devices.

An exemplary embodiment of the present invention is a semiconductor device, including: a semiconductor material and an electrode structure electrically coupled to the semiconductor material. The electrode structure includes: a first portion formed of a first conductive material and a second portion formed of a second conductive material. Both the first portion and the second portion of the electrode structure are in direct contact with the semiconductor material. The first conductive material has a first work function and the second conductive material has a second work function that is different from the first work function, so that the second portion of the electrode structure forms a junction with the first portion. The first portion and the second portion of the electrode structure are arranged such that the fringe field from the edge of this junction between the first portion and the second portion extends into the semiconductor material.

Another exemplary embodiment of the present invention is a method of manufacturing a semiconductor device. A first conductive material is disposed on the top surface of a semiconductor material such that the first conductive material covers only a first area of the top surface of the semiconductor material. A layer of a second conductive material is formed over the first conductive material and a second area of the top surface of the semiconductor material. The first conductive material has a first work function and the second conductive material has a second work function that is different from the first work function. The first portion and the second portion of the electrode structure are arranged such that the fringe field from the edge of a junction between the first portion and the second portion extends into the semiconductor material.

A further exemplary embodiment of the present invention is a method of manufacturing a semiconductor device. A first conductive material is disposed on the top surface of a second conductive material such that the first conductive material covers only a first area of the top surface of the second conductive material. The first conductive material has a first work function and the second conductive material has a second work function that is different from the first work function. A layer of a semiconductor material is formed over the first conductive material and a second area of the top surface of the second conductive material. The first portion and the second portion of the electrode structure are arranged such that the fringe field from the edge of a junction between the first portion and the second portion extends into the semiconductor material.

An additional embodiment of the present invention is a method of manufacturing a semiconductor device. An electrode structure, having a Lamera structure that includes layers of a first conductive material and layers of a second conductive material, is formed. The first conductive material has a first work function and the second conductive material has a second work function that is different from the first work function. A layer of a semiconductor material on a surface of the electrode structure that is substantially perpendicular to the layers of the first second conductive materials. The electrode structure is arranged such that fringe fields from the edges of the junctions between the layers of the first and second conductive materials extend into the semiconductor material.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawing are the following figures:

FIGS. 1A and 1B are side plan drawings illustrating exemplary electrode structures for improved charge injection according to the present invention.

FIGS. 1C, 1D, and 1E are top plan drawings illustrating alternative exemplary configurations of the conductive materials in the exemplary electrode structures of FIGS. 1A and 1B.

FIG. 2 is a side plan drawing illustrating another exemplary electrode structure for improved charge injection according to the present invention.

FIGS. 3A and 3B are side plan drawings illustrating further exemplary electrode structures for improved charge injection according to the present invention.

FIG. 3C is a top plan drawing illustrating an exemplary configuration of the conductive materials in the electrode structure for improved charge injection of FIG. 3A.

FIG. 4 is a flow chart illustrating an exemplary method of forming an exemplary semiconductor device including an electrode structure for improved charge injection, such as the exemplary structures of FIGS. 1B, 1C, 1D, 1E, 3B, and 3C.

FIG. 5 is a flow chart illustrating another exemplary method of forming an exemplary semiconductor device including an electrode structure for improved charge injection, such as the exemplary structures of FIGS. 1A, 1C, 1D, 1E, 3A, and 3C.

FIG. 6 is a flow chart illustrating a further exemplary method of forming an exemplary semiconductor device including an electrode structure for improved charge injection, such as the exemplary structure of FIG. 2.

### DETAILED DESCRIPTION OF THE INVENTION

Exemplary embodiments of the present invention use two different conductors that have different work functions (WF's) to enhance charge injection into semiconductor devices, such as electroluminescent (EL) or thin film transistor (TFT) devices. These exemplary embodiments may also be used to enhance charge extraction from semiconductor devices, such as photovoltaic detectors and solar cells. The exemplary electrode structure formed by these two conductive materials creates a fringe field at the edge of the interface, or junction, between the two conductors. The resulting fringe field may improve charge injection into adjacent regions of semiconductor material. If the ratio of the length of such junction edges to the surface area of the electrode to semiconductor contact is sufficiently high, the resulting charge injection enhancement may be significant. This ratio may be increased by creating small islands of one of the conductors on the electrode contact surface, possibly even nanoscale dots (i.e. nano dots). These exemplary embodiments may reduce the need for high doping concentrations to form ohmic contact; may improve charge extraction from photovoltaic devices; and/or may improve the efficiency of charge injection in devices such as TFT devices, EL devices, organic light emitting diodes (OLED's), and polymer light emitting diodes (PLED's).

It is noted that exemplary embodiments of the present invention may be used as electron and/or hole injection layers or electron and/or hole extraction layers. Exemplary embodiments of the present invention may also enable the production of relatively air stable cathode structures compared to prior art cathodes that have included alkali and alkali earth metals such as calcium, barium, and lithium.

Exemplary method of manufacturing such electrode structures may include forming nano sized dots of one conductor on the surface of another conductor, or phase separation of two or more conductors (i.e. forming Lamera structures).

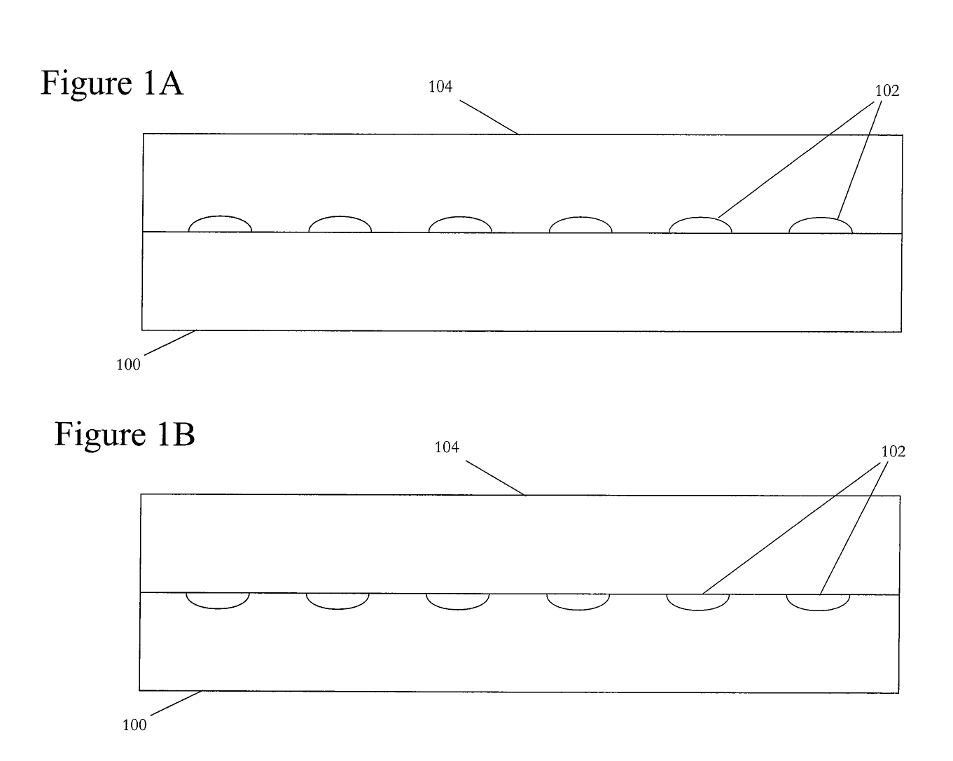

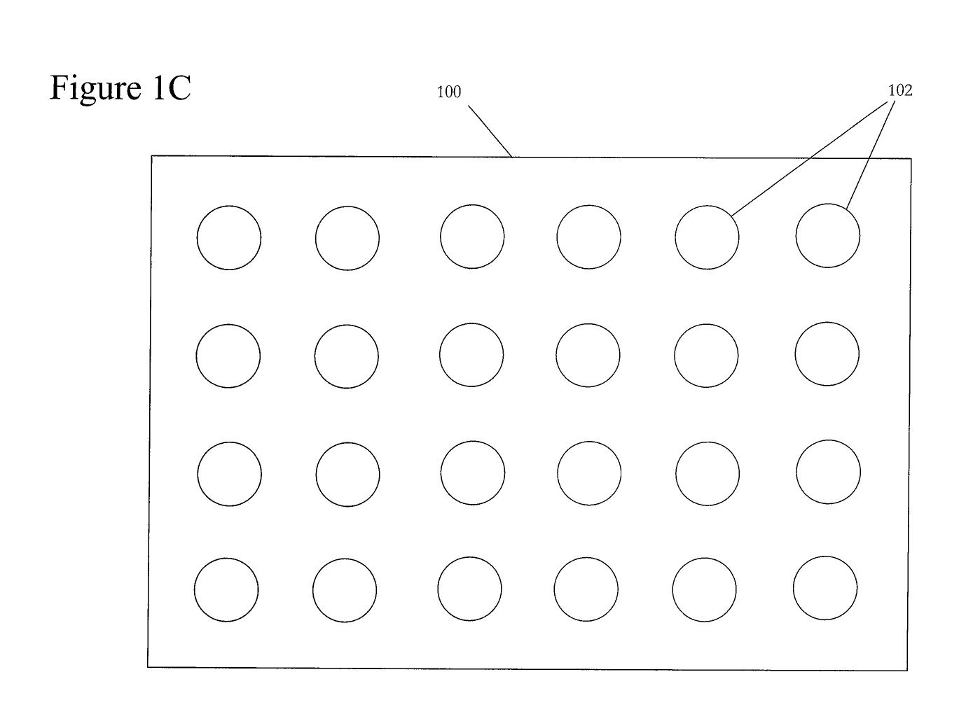

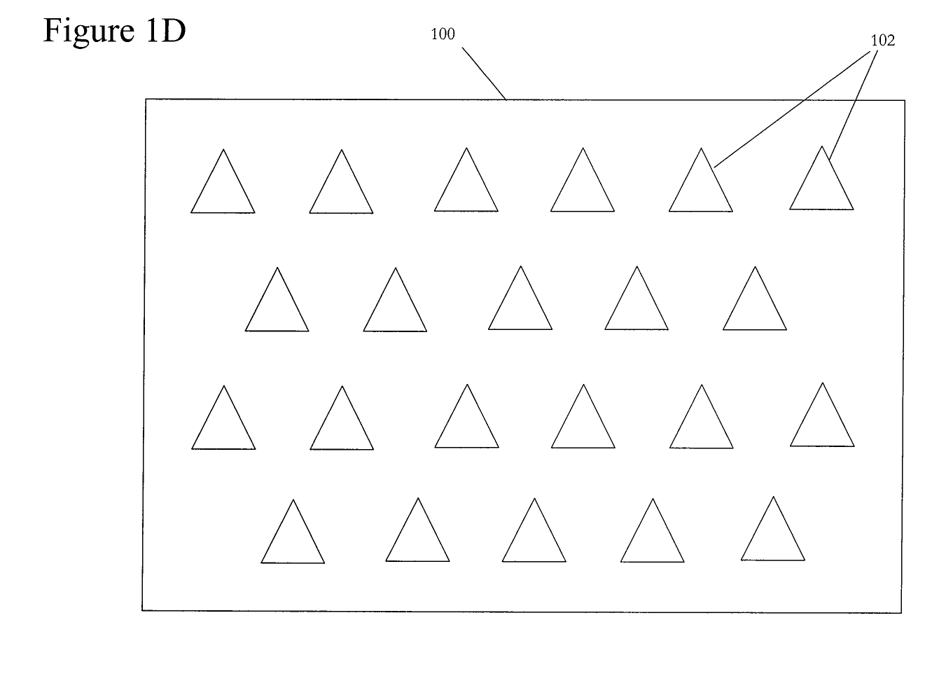

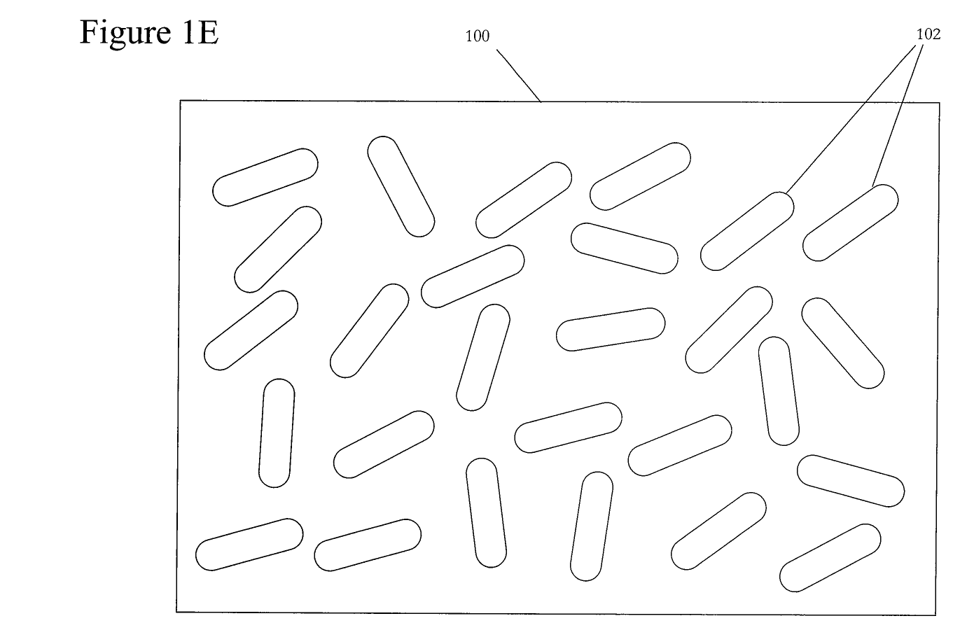

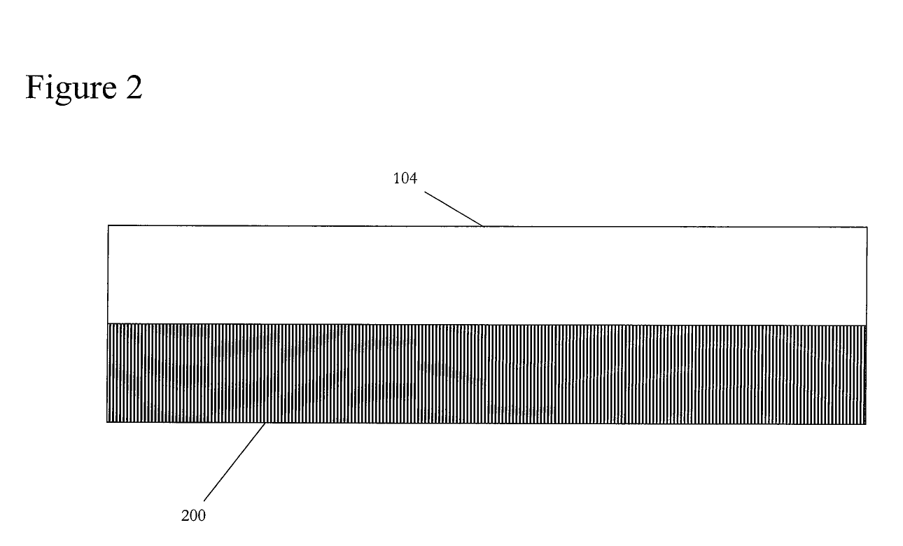

FIGS. 1A-E illustrate exemplary semiconductor devices according to the present invention. FIGS. 1A and 1B illustrate side plan views of two exemplary embodiments including: two conductive materials 100 and 102; and semiconductor material 104. In FIG. 1A, conductive material 102 is formed as a plurality of islands on a substantially flat top surface of conductive material 100, while, in FIG. 1A, conductive material 102 is formed in a plurality of depressions in the top surface of conductive material 100. FIGS. 1C-E illustrate top plan views of three exemplary configurations of the electrode structures of the exemplary embodiments of FIGS. 1A and 1B, with semiconductor layer 104 removed. It is noted that, due to the random orientation of the islands of conductive material 104, the exemplary configuration illustrated in FIG. 1E does not directly correspond to the illustrations of FIGS. 1A and 1B.

The electrode structure formed by conductive materials 100 and 102 is electrically coupled to semiconductor 104. It is noted that semiconductor layer 104 may be formed of organic semiconductor material, inorganic semiconductor material, or a combination thereof. Structures may be formed within semiconductor layer 104 by means known in the art such as doping, etching, deposition, etc. Additionally, semiconductor layer 104 may include multiple sub-layers to form various structures such as PN junctions or quantum well structures.

Both the first portion of the electrode structure (conductive material 100) and the second portion of the electrode structure (conductive material 102) are in direct contact with semiconductor material 104. The conductive materials of these two portions have different work functions so that each junction between the first portion and the second portion of the electrode structure acts like a miniature battery. These conductive materials may be metals or other conductive materials, such as polysilicon and organic conductors.

Because of the difference in the work functions of conductive materials 100 and 102, charges transfer across these junctions creating a built-in electric field. Thus, at the edges of these junctions, a fringe field extends into semiconductor material 104. The difference between the work functions of exemplary conductive material 100 and exemplary conductive material 102 is greater than 0.2 eV, depending on the amount of fringe field desired.

This fringe field assists charge transfer between the electrode and semiconductor material 104 (i.e. charge injection or extraction) in the regions of the electrode/semiconductor contact near the junctions. For example, if the work function of the first portion of the electrode structure (conductive material 100), which is electrically connected to an external voltage source, is greater than the work function of the second portion of the electrode structure (conductive material 102), then the electrode structure may exhibit fringe-field assisted electron injection into semiconductor material 104, or fringe-field assisted hole extraction from semiconductor material 104. Conversely, if the work function of the first portion of the electrode structure (conductive material 100) is less than the work function of the second portion of the electrode structure (conductive material 102), then the electrode structure may exhibit fringe-field assisted hole injection into semiconductor material 104, or fringe-field assisted electron extraction from semiconductor material 104.

Another potential feature of the exemplary electrode structures of FIGS. 1A-E is that conductive material 100 and semiconductor material 104 surround the islands of conductive material 102 so that they may substantially prevent interaction between conductive material 102 and external fluids, such as air or a liquid that may surround the electronic device. This feature may be particularly desirable for electrode structures designed to improve electron injection into semiconductor material 104 (or hole extraction from semiconductor material 104). In such electrode structures, it may be desirable to use conductive materials with very low work functions, such as alkali metals or alkali earth metal, for conductive material 102.

The exemplary electrode structures illustrated in FIGS. 1A-E all include configurations in which conductive material 102 is in the form of a plurality of islands formed between the top surface of conductive material 100 and the bottom surface of semiconductor material 104. As shown in FIGS. 1C-E, these islands may have substantially uniform shapes; however non-uniformly shaped islands of conductive material 102 may be formed as well. Additionally, the circular, triangular, and oval islands illustrated in FIGS. 1C-E are merely illustrative, and are not intended to be limiting. Other island shapes including various polygons, star-like shapes and irregular shapes are contemplated as well. It is noted that islands having a large circumference to volume ratio may be particularly desirable. Further, the semi-elliptical profiles illustrated in FIGS. 1A and 1B are also merely illustrative, and not intended to be limiting. For example, islands having substantially triangular or rectangular side profiles are contemplated.

In one exemplary embodiment, each of the islands may be a pre-formed nanoparticle of the second conductive material. Such nanoparticle islands may be formed of a variety of nanostructured materials including conductive quantum dots, polymer chains, and fullerenes.

In another exemplary embodiment, a conductor, such as a metal, may be deposited using a thin film deposition technique to form island(s). Such thin film deposition techniques may include: evaporation; sputtering; spin coating; ink jet printing; and various epitaxial methods, including atomic layer deposition, among others. These techniques may be used to form islands of the second conductive material that are very thin.

These islands of conductive material 102 may be arranged in a substantially uniform pattern as illustrated in FIGS. 1C and 1D, or they may be arranged in a random pattern, as illustrated in FIG. 1E.

FIG. 2 illustrates an alternative exemplary semiconductor device in which electrode structure 200 is a Lamera structure. This exemplary electrode structure includes a series of layers that are disposed substantially perpendicularly to the interface between electrode structure 200 and semiconductor material 104. A first subset of this series of layers in the Lamera structure is formed of the first conductive material and a second subset of the series of layers is formed of the second conductive material.

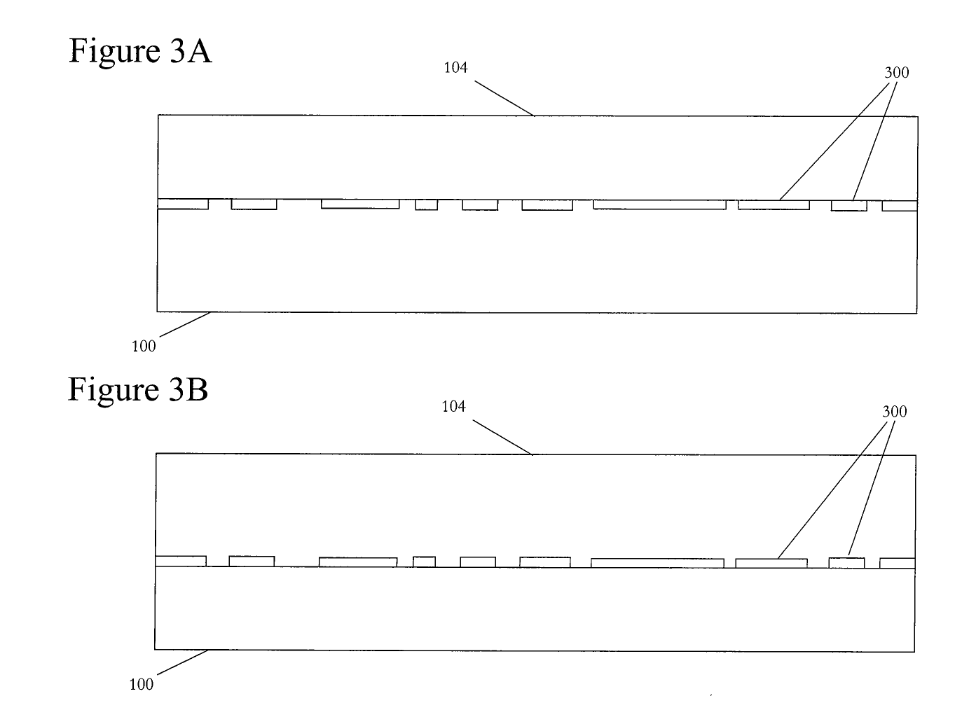

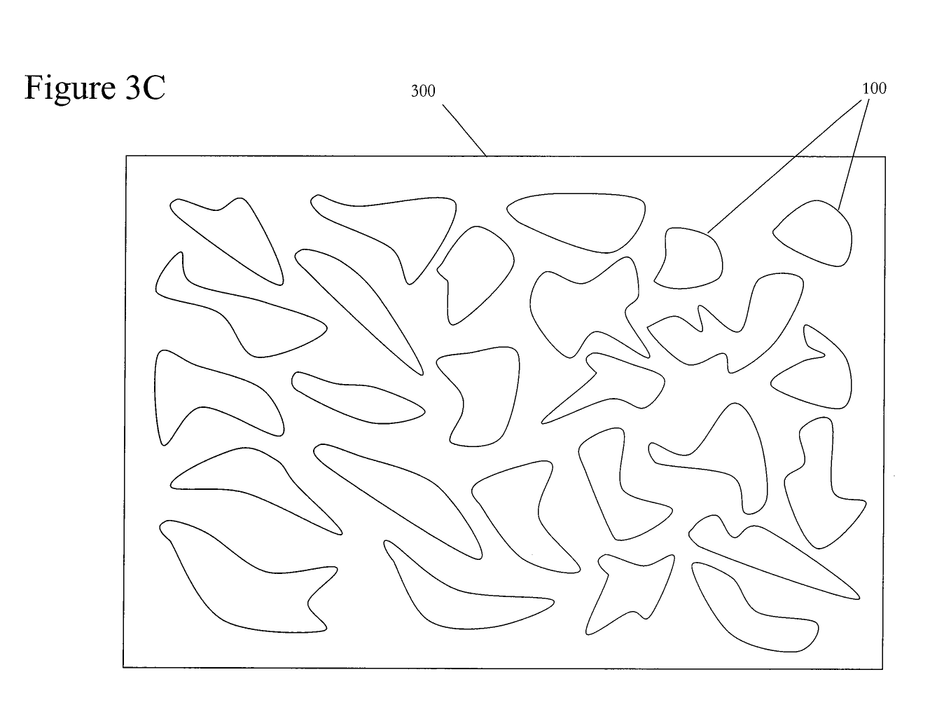

FIGS. 3A-C illustrates additional exemplary semiconductor devices according to the present invention. In these exemplary embodiments, the second portion of the electrode structure is porous layer 300, which is formed of the second conductive material. Porous layer 300 is formed between the top surface of conductive material 100 and the bottom surface of semiconductor material 104. Conductive material 100 and semiconductor material 104 directly contact through pores in porous layer 300. FIG. 3A illustrates an exemplary embodiment in which conductive material 100 extends through the pores and FIG. 3B illustrates an exemplary embodiment in which semiconductor material 104 extends through the pores. FIG. 3C illustrates a top plan view of the exemplary embodiments of FIGS. 3A and 3B with semiconductor material 104 removed. It is noted that FIGS. 3A-C all show porous layer 300 to include irregular pores; however it is contemplated that porous layer 300 could be formed with an regular array of pores as well.

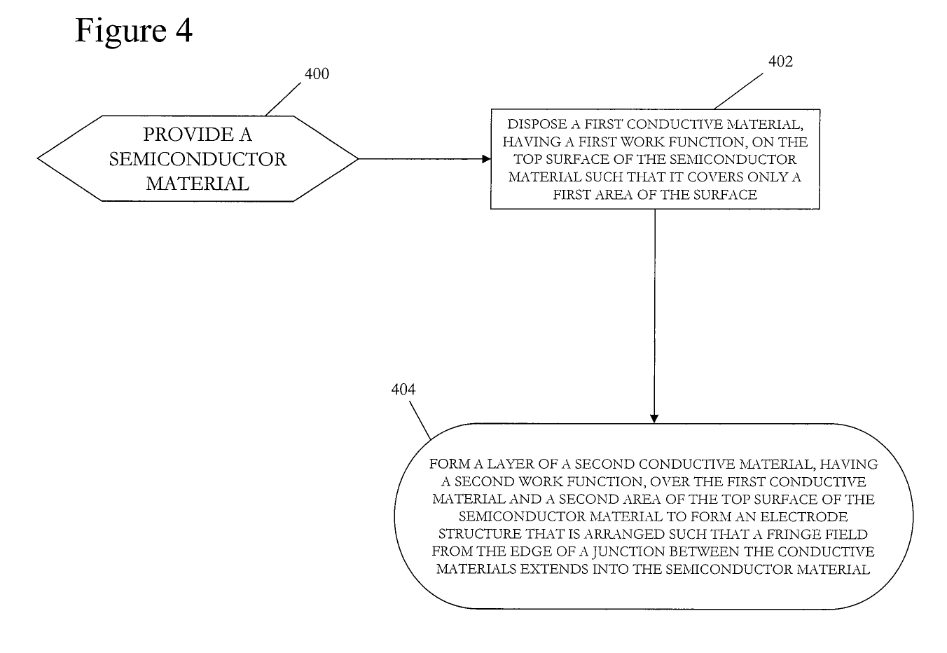

FIG. 4 illustrates an exemplary method of manufacturing a semiconductor device including an exemplary electrode structures similar to those illustrated in FIGS. 1B, 1C, 1D, 1E, 3B, and 3C.

A semiconductor material is provided, step 400. A first conductive material is disposed on the top surface of this semiconductor material such that the first conductive material covers only part of the top surface of the semiconductor material, step 402. This first conductive material has a first work function. The first conductive material may be disposed on the semiconductor material using any standard semiconductor fabrication techniques, including: sputtering, evaporation, epitaxial deposition; ink jet printing; spin coating; and atomic layer deposition.

The first conductive material may be disposed only on the desired area(s) of the surface of the semiconductor material using techniques such as masking and selective area growth. Alternatively, the first conductive material may be deposited as a solid layer on the top surface of the semiconductor material and then this layer may be etched to form the desired pattern of the first conductive material.

Various deposition techniques, including atomic layer deposition, may be used to form a porous layer of the conductive material.

In an alternative exemplary embodiment, nanoparticles of the first conductive material may be deposited on the top surface of the semiconductor material to form a plurality of islands on the top surface of the semiconductor material.

A layer of a second conductive material is then formed over the first conductive material and remaining area(s) of the top surface of the semiconductor material, step 404. The second conductive material has a second work function that is different than the first work function of the first conductive material. This layer of the second conductive material may be formed using any standard semiconductor fabrication technique.

As described above with regard to FIGS. 1-3, the resulting electrode structure formed by the first and second conductive materials is arranged such that a fringe field from the edge of the junction between the first conductive material and the second conductive material extends into the semiconductor material. Additionally, the layer of the second conductive material may be formed over the first conductive material and the second area of the top surface of the semiconductor material so as to substantially encapsulate the first conductive material, thereby substantially preventing interaction between the first conductive material and external fluids.

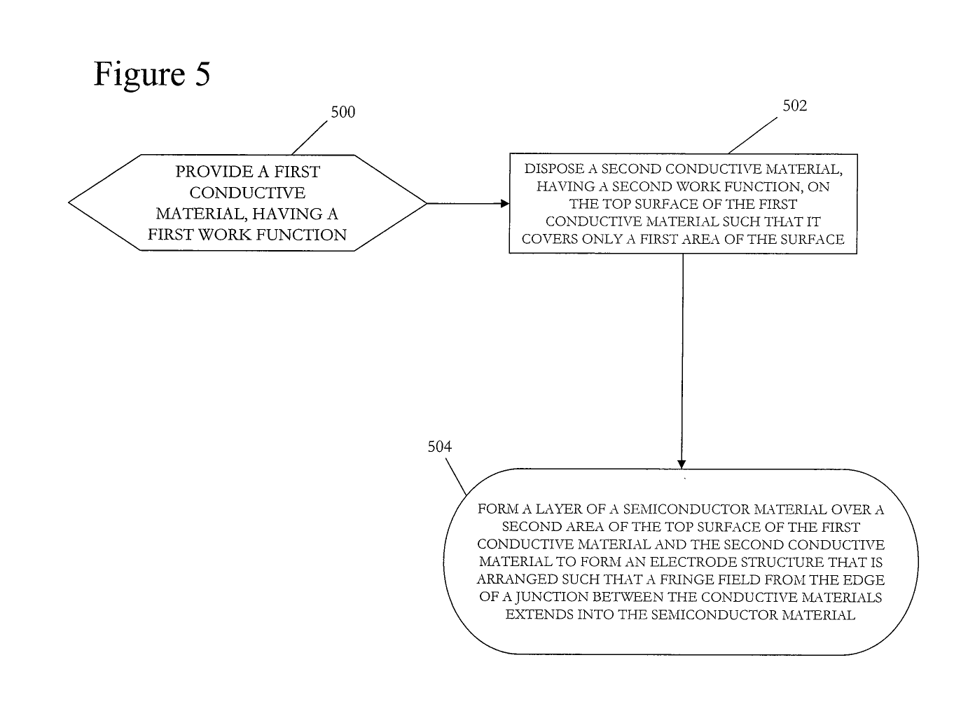

FIG. 5 illustrates another exemplary method of manufacturing a semiconductor device including an exemplary electrode structures similar to those illustrated in FIGS. 1A, 1C, 1D, 1E, 3A, and 3C. This exemplary method is very similar to the exemplary method of FIG. 4.

A first conductive material is provided, step 500. This first conductive material has a first work function. A second conductive material is disposed on the top surface of this first conductive material such that the second conductive material covers only part of the top surface of the first conductive material, step 502. This second conductive material has a second work function that is different than the first work function of the first conductive material. The second conductive material may be disposed on the first conductive material using any standard semiconductor fabrication techniques, as described above for disposing the first conductive material on the semiconductor material in step 402 of the exemplary method of FIG. 4.

A layer of a semiconductor material is then formed over the second conductive material and remaining area(s) of the top surface of the first conductive material, step 504. This layer of semiconductor material may be formed using any standard semiconductor fabrication technique.

As described above with regard to FIGS. 1-4, the resulting electrode structure formed by the first and second conductive materials is arranged such that a fringe field from the edge of the junction between the first conductive material and the second conductive material extends into the semiconductor material. Additionally, the layer of the semiconductor material may be formed over the second conductive material and the second area of the top surface of the first conductive material so as to substantially encapsulate the second conductive material, thereby substantially preventing interaction between the second conductive material and external fluids.

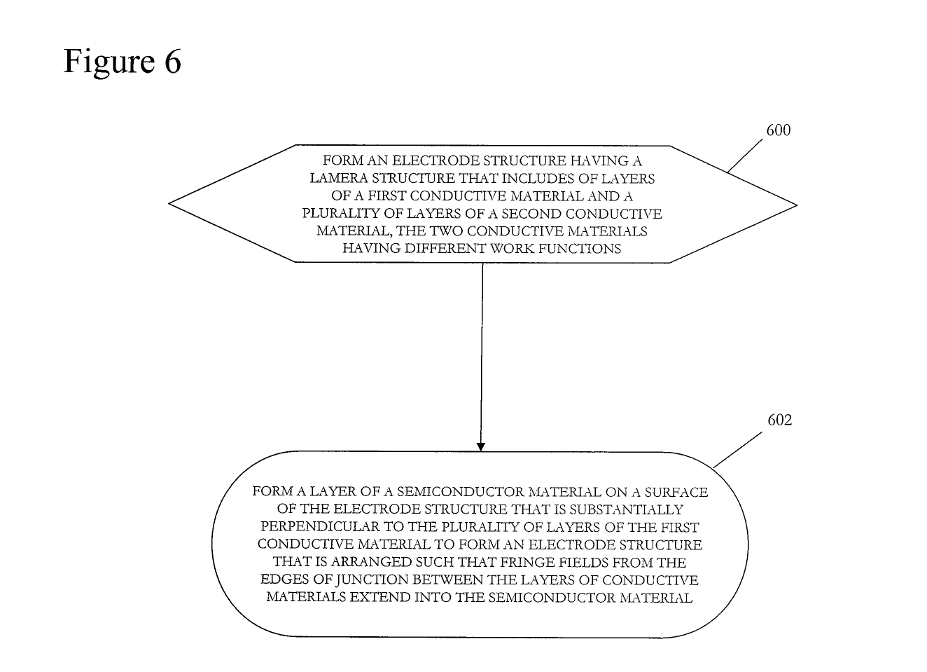

FIG. 6 illustrates a further exemplary method of manufacturing a semiconductor device, which includes an exemplary Lamera structure as illustrated in FIG. 2. An electrode structure having a Lamera structure is formed, step 600. The Lamera structure includes one set of layers of a first conductive material and another set of layers of a second conductive material. The first conductive material has a first work function and the second conductive material has a second work function that is different than the first work function.

A layer of semiconductor material is formed on a surface of the electrode structure that is substantially perpendicular to the layers of the first and second conductive materials, step 602. Thus, the electrode structure is arranged such that fringe fields from edges of junctions between layers of the first conductive material and layers of the second conductive material extend into the semiconductor material. The layer of semiconductor material may be formed using any standard semiconductor fabrication techniques.

The exemplary methods described herein may be used to form anodes and/or cathodes. These exemplary electrode structures of the present invention may have numerous applications in many electronic devices, such as electroluminescent, switching, and photovoltaic devices. Display and lighting apparatus may particularly benefit from fringe field assisted charge injection as described in the exemplary embodiments above.

The present invention includes a number of exemplary semiconductor devices and exemplary methods of manufacturing these devices. Although the invention is illustrated and described herein with reference to specific embodiments, it is not intended to be limited to the details shown. Rather, various modifications may be made in the details within the scope and range of equivalents of the claims and without departing from the invention. In particular, one skilled in the art may understand that the invention is not limited to electrode structures including only two conductive materials; electrode structures including three or more conductive materials are also embodied by the present invention. Additionally, features of the various specifically illustrated embodiments may be mixed to form additional exemplary electronic devices that are also embodied by the present invention.

What is claimed:

1. A semiconductor device, comprising:
a semiconductor material; and
an electrode structure electrically coupled to the semiconductor material, the electrode structure including:
a first portion formed of a first conductive material that has a first work function, the first portion of the electrode structure being in direct contact with the semiconductor material; and
a second portion formed of a second conductive material that has a second work function which is different from the first work function, the second portion of the electrode structure forming a junction with the first portion of the electrode structure and being in direct contact with the semiconductor material;
wherein the first portion and the second portion of the electrode structure are arranged such that a fringe field from an edge of the junction between the first portion and the second portion extends into the semiconductor material.

2. A semiconductor device according to claim 1, wherein the semiconductor material is one of an organic semiconductor material or an inorganic semiconductor material.

3. A semiconductor device according to claim 1, wherein:
the electrode structure is a Lamera structure including a series of layers that are disposed substantially perpendicularly to an interface between the electrode structure and the semiconductor material;
the first portion of the electrode structure being a first subset of the series of layers of the Lamera structure; and
the second portion of the electrode structure being a second subset of the series of layers of the Lamera structure.

4. A semiconductor device according to claim 1, wherein the second portion of the electrode structure includes a plurality of islands of the second conductive material formed between a top surface of the first portion of the electrode structure and a bottom surface of the semiconductor material.

5. A semiconductor device according to claim 4, wherein the plurality of islands of the second conductive material are arranged in a substantially uniform pattern.

6. A semiconductor device according to claim 4, wherein the plurality of islands of the second conductive material have a substantially uniform shape.

7. A semiconductor device according to claim 6, wherein each of the plurality of islands is a preformed nanoparticle of the second conductive material.

8. A semiconductor device according to claim 7, wherein the preformed nanoparticles are fullerenes.

9. A semiconductor device according to claim 1, wherein:
the second portion of the electrode structure is a porous layer of the second conductive material formed on a top surface of the first portion of the electrode structure, the porous layer including a plurality of pores; and
the first portion of the electrode structure directly contacting the semiconductor material through the plurality of pores in the second portion of the electrode structure.

10. A semiconductor device according to claim 1, wherein the second portion of the electrode structure is formed between a top surface of the first portion of the electrode structure and a bottom surface of the semiconductor material such that the first portion of the electrode structure and the semiconductor material substantially prevent interaction between the second portion of the electrode structure and external fluids.

11. A semiconductor device according to claim 10, wherein the second conductive material is one of an alkali metal or an alkali earth metal.

12. A semiconductor device according to claim 1, wherein:
the first portion of the electrode structure is electrically connected to an external voltage source;
the first work function is greater than the second work function; and
the electrode structure exhibits one of fringe-field assisted electron injection or fringe-field assisted hole extraction.

13. A semiconductor device according to claim 1, wherein:
the first portion of the electrode structure is electrically connected to an external voltage source;
the first work function is less than the second work function; and
the electrode structure exhibits one of fringe-field assisted hole injection or fringe-field assisted electron extraction.

14. A semiconductor device according to claim 1, wherein a difference between the first work function and the second work function is greater than about 0.2 eV.

15. A method of manufacturing a semiconductor device, comprising the steps of:
a) disposing a first conductive material on a top surface of a semiconductor material such that the first conductive material covers only a first area of the top surface of the semiconductor material, the first conductive material having a first work function; and
b) forming a layer of a second conductive material over the first conductive material and a second area of the top surface of the semiconductor material, the second conductive material having a second work function that is different than the first work function;
wherein the first conductive material and the second conductive material form an electrode structure that is arranged such that a fringe field from an edge of a junction between the first conductive material and the second conductive material extends into the semiconductor material.

16. A semiconductor device according to claim 15, wherein step (a) includes disposing the first conductive material as a plurality of islands on the first area of the top surface of the semiconductor material.

17. A semiconductor device according to claim 15, wherein step (a) includes depositing a porous layer of the first conductive material on the top surface of the semiconductor material.

18. A semiconductor device according to claim 15, wherein step (a) includes at least one of:
depositing the first conductive material on the top surface of the semiconductor material using a sputtering technique;
depositing the first conductive material on the top surface of the semiconductor material using an evaporation deposition technique;
depositing the first conductive material on the top surface of the semiconductor material using an epitaxial deposition technique;
depositing the first conductive material on the top surface of the semiconductor material using ink jet printing;
depositing the first conductive material on the top surface of the semiconductor material using a spin coating technique; and
depositing the first conductive material on the top surface of the semiconductor material using an atomic layer deposition technique.

19. A semiconductor device according to claim 15, wherein step (b) includes forming the layer of the second conductive material over the first conductive material and the second area of the top surface of the semiconductor material such that the layer of the second conductive material and the semiconductor material substantially encapsulate the first conductive material disposed in step (a), thereby substantially preventing interaction between the first conductive material and external fluids.

20. A method of manufacturing a semiconductor device, comprising the steps of:
a) disposing a first conductive material on a top surface of a second conductive material such that the first conductive material covers only a first area of the top surface of the second conductive material, the first conductive material having a first work function and the second conductive material having a second work function that is different than the first work function; and
b) forming a layer of a semiconductor material over the first conductive material and a second area of the top surface of the second conductive material;
wherein the first conductive material and the second conductive material form an electrode structure that is arranged such that a fringe field from an edge of a junction between the first conductive material and the second conductive material extends into the semiconductor material.

21. A semiconductor device according to claim 20, wherein step (a) includes disposing the first conductive material as a plurality of islands on the first area of the top surface of the second conductive material.

22. A semiconductor device according to claim 20, wherein step (a) includes depositing a porous layer of the first conductive material on the top surface of the second conductive material.

23. A semiconductor device according to claim 20, wherein step (a) includes at least one of:
depositing the first conductive material on the top surface of the semiconductor material using a sputtering technique;
depositing the first conductive material on the top surface of the semiconductor material using an evaporation deposition technique;
depositing the first conductive material on the top surface of the semiconductor material using an epitaxial deposition technique;
depositing the first conductive material on the top surface of the semiconductor material using ink jet printing;
depositing the first conductive material on the top surface of the semiconductor material using a spin coating technique; and
depositing the first conductive material on the top surface of the semiconductor material using an atomic layer deposition technique.

24. A semiconductor device according to claim 20, wherein step (b) includes forming the layer of the semiconductor material over the first conductive material and the second area of the top surface of the second conductive material such that the layer of the second conductive material and the semiconductor material substantially encapsulate the first conductive material disposed in step (a), thereby substantially preventing interaction between the first conductive material and external fluids.

25. A method of manufacturing a semiconductor device, comprising the steps of:
a) forming an electrode structure having a Lamera structure that includes a plurality of layers of a first conductive material and a plurality of layers of a second conductive material, the first conductive material having a first work function and the second conductive material having a second work function that is different than the first work function; and
b) forming a layer of a semiconductor material on a surface of the electrode structure that is substantially perpendicular to the plurality of layers of the first conductive material and the plurality of layers of the second conductive material;
wherein the electrode structure is arranged such that fringe fields from edges of junctions between layers of the first conductive material and layers of the second conductive material extend into the semiconductor material.
